(19) United States
(12) Patent Application Publication
(10) Pub. No.: US 2022/0084799 A1
(43) Pub. Date: Mar. 17, 2022

(54) SEMICONDUCTOR MANUFACTURING APPARATUS

(71) Applicant: Kioxia Corporation, Tokyo (JP)

(72) Inventors: Motoki FUJII, Yokkaichi (JP); Daisuke NISHIDA, Mie (JP)

(73) Assignee: Kioxia Corporation, Tokyo (JP)

(21) Appl. No.: 17/466,285

(22) Filed: Sep. 3, 2021

(30) Foreign Application Priority Data
Sep. 16, 2020 (JP) 2020-155722

(51) Int. Cl. H01J 37/32; C23C 8/12; C23C 8/24; C23C 8/36

(52) U.S. Cl. CPC H01J 37/32669; H01J 37/32467; H01J 37/3244; H01L 21/0223; C23C 8/24; C23C 8/36; C23C 8/12

(57) ABSTRACT

A semiconductor manufacturing apparatus according to an embodiment includes: a chamber that houses a semiconductor substrate; and a plurality of coils provided on a lateral surface of the chamber. The chamber has a first spatial region enclosed above the semiconductor substrate by a first coil that is one of the plurality of coils, a first gas introduction port communicating with the first spatial region, a second spatial region enclosed by a second coil that is different from the first coil among the plurality of coils, and a second gas introduction port communicating with the second spatial region.

### CROSS-REFERENCE TO RELATED APPLICATIONS

This application is based upon and claims the benefit of priority from Japanese Patent Application No. 2020-155722, filed on Sep. 16, 2020; the entire contents of which are incorporated herein by reference.

### FIELD

Embodiments of the present invention relate to a semiconductor manufacturing apparatus.

### BACKGROUND

One of semiconductor manufacturing apparatuses is a plasma processing apparatus. In the plasma processing apparatus, plasma is generated in a chamber when a current is caused to flow through a coil enclosing the chamber and gas is introduced. This plasma generates radicals. With these radicals, processing such, for example, as oxidation or nitridation is performed on a film formed on a semiconductor substrate.

### BRIEF DESCRIPTION OF THE DRAWINGS

FIG. 1 is a schematic diagram schematically showing a configuration of a semiconductor manufacturing apparatus according to a first embodiment;

FIG. 2 is a cross sectional view showing a schematic structure of a semiconductor manufacturing apparatus according to a comparative example;

FIG. 3 is a cross sectional view showing a structure of the part of a semiconductor manufacturing apparatus according to a first modification;

FIG. 4 is a cross sectional view showing a schematic structure of a semiconductor manufacturing apparatus according to a second modification;

FIG. 5 is a cross sectional view showing a schematic structure of a semiconductor manufacturing apparatus according to a second embodiment; and

FIG. 6 is a cross sectional view showing a schematic structure of a semiconductor manufacturing apparatus according to a third modification.

### DETAILED DESCRIPTION

Embodiments will now be explained with reference to the accompanying drawings. The present invention is not limited to the embodiments.

A semiconductor manufacturing apparatus according to an embodiment includes: a chamber that houses a semiconductor substrate; and a plurality of coils provided on a lateral surface of the chamber. The chamber has a first spatial region enclosed above the semiconductor substrate by a first coil that is one of the plurality of coils, a first gas introduction port communicating with the first spatial region, a second spatial region enclosed by a second coil that is different from the first coil among the plurality of coils, and a second gas introduction port communicating with the second spatial region.

### First Embodiment

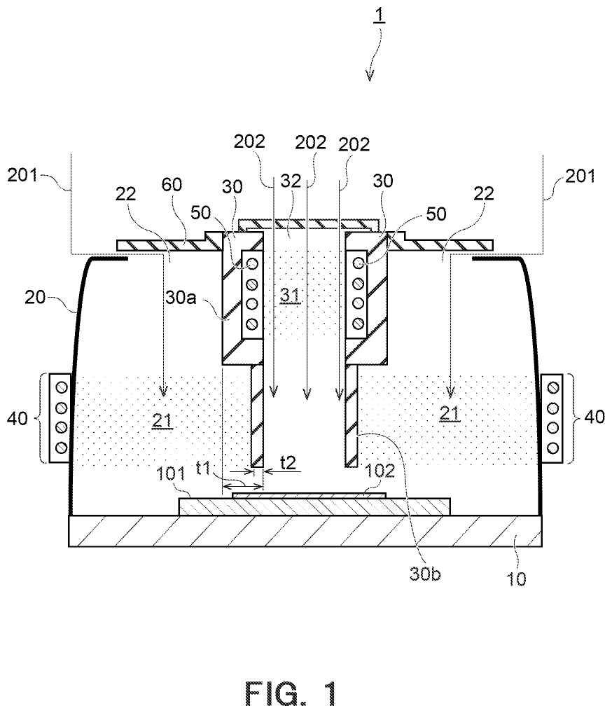

FIG. 1 is a cross sectional view showing a schematic structure of a semiconductor manufacturing apparatus according to a first embodiment. A semiconductor manufacturing apparatus 1 shown in FIG. 1 includes a stage 10, a first quartz tube 20, a second quartz tube 30, a first coil 40, a second coil 50 and a shower plate 60. The semiconductor manufacturing apparatus 1 according to the present embodiment is a plasma processing apparatus which performs processing such as oxidation or nitridation on a film 102 formed on an upper surface of a semiconductor substrate 101.

The semiconductor substrate 101 is placed on the stage 10. The film 102 formed on the upper surface of the semiconductor substrate 101 is a metal film containing tungsten (W), for example.

The first quartz tube 20 and the second quartz tube 30 constitute a chamber and have a multiple tube structure in which they are concentrically arranged. Notably, this multiple tube structure may include three or more quartz tubes which are concentrically arranged.

First, the first quartz tube 20 is described. The first quartz tube 20 houses the semiconductor substrate 101 and has a first spatial region 21 and a first gas introduction port 22. The first spatial region 21 is an internal space, of the first quartz tube 20, which space is enclosed above the semiconductor substrate 101 by the first coil 40.

The first gas introduction port 22 is formed in an upper surface of the first quartz tube 20 and communicates with the first spatial region 21. A first gas 201 is introduced to the first gas introduction port 22. The first gas 201 is an oxygen (O₂) gas, a nitrogen (N₂) gas, a hydrogen (H₂) gas, or a gas having those gases mixed, for example.

Subsequently, the second quartz tube 30 is described. The second quartz tube 30 is arranged above the center part of the semiconductor substrate 101 (film 102) in the first quartz tube 20, and has a first tubular part 30a and a second tubular part 30b. The first tubular part 30a has a second spatial region 31 and a second gas introduction port 32. The second spatial region 31 is an internal space, of the first tubular part 30a, which space is enclosed above the first spatial region 21 by the second coil 50.

The second gas introduction port 32 is formed in an upper surface of the first tubular part 30a and communicates with the second spatial region 31. To the second gas introduction port 32, a second gas 202 is introduced simultaneously with the first gas 201. The second gas 202 is the same kind of gas as the first gas 201.

The second tubular part 30b protrudes from the bottom part of the first tubular part 30a toward the first spatial region 21. The second tubular part 30b separates a flow channel of the second gas 202 from a flow channel of the first gas 201 (first spatial region 21). Therefore, the first gas 201 and the second gas 202 are scarcely mixed. In order to prevent mixing of the first gas 201 and the second gas 202, the second tubular part 30b desirably elongates to the same level as that of the lower end part of the first coil 40. In other words, the bottom part of the second tubular part 30b and the lower end part of the first coil 40 desirably have the same heights from the semiconductor substrate 101.

Since as to the second quartz tube 30 of the present embodiment, an opening diameter of the second tubular part 30b is equal to an opening diameter of the first tubular part 30a, the flow of radicals generated in the first tubular part 30a is not disturbed by the second tubular part 30b. When a thickness “t2” of the second tubular part 30b is large, generation of radicals by the first coil 40 is disturbed. The thickness “t2” of the second tubular part 30b is desirably smaller than a thickness “t1” of the first tubular part 30a in order to restrain the generation of radicals from being disturbed.

The first coil 40 is provided on a lateral surface of the first quartz tube 20. When a current flows through the first coil 40 and the first gas 201 is introduced from the first gas introduction port 22, plasma is generated in the first spatial region 21. This plasma generates radicals of molecules contained in the first gas 201. These radicals oxidize or nitride the peripheral part of the film 102. Notably, while in FIG. 1, the first coil 40 is provided on the outer side of the lateral surface of the first quartz tube 20, it may be provided on the inner side of the lateral surface.

The second coil 50 is provided on a lateral surface of the first tubular part 30a. When a current flows through the second coil 50, plasma is generated in the second spatial region 31. This plasma generates radicals of molecules contained in the second gas 202. These radicals oxidize or nitride the center part of the film 102. In the present embodiment, the second coil 50 is set such that a density of the radicals generated in the second spatial region 31 is equal to a density of the radicals generated in the first spatial region 21. For example, as to the second coil 50, the coil length, the number of windings, and the current are set to the same values as those for the first coil 40.

The shower plate 60 is provided on the upper surfaces of the first quartz tube 20 and the second quartz tube 30. The shower plate 60 guides the first gas 201 to the first gas introduction port 22 and guides the second gas 202 to the second gas introduction port 32.

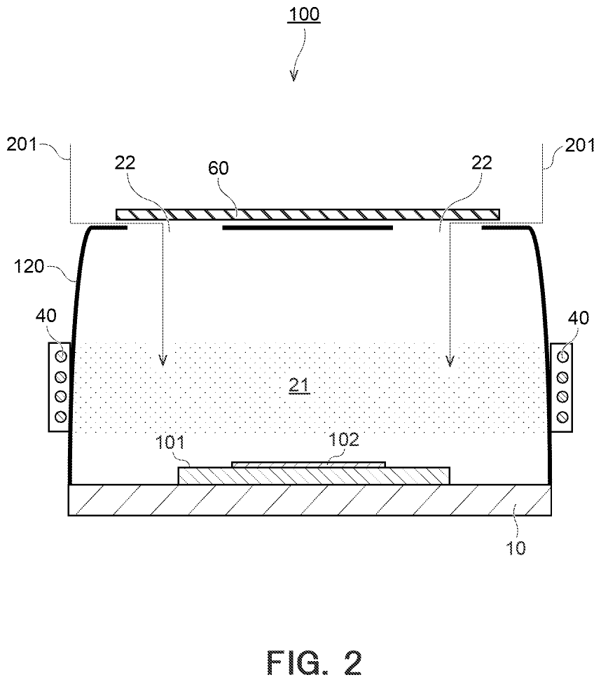

Hereafter, a semiconductor manufacturing apparatus according to a comparative example is described with reference to FIG. 2. FIG. 2 is a cross sectional view showing a schematic structure of the semiconductor manufacturing apparatus according to the comparative example. The similar constituents to those of the semiconductor manufacturing apparatus 1 shown in FIG. 1 are given the same signs and their detailed description is omitted.

In a semiconductor manufacturing apparatus 100 shown in FIG. 2, while the first coil 40 is provided on a lateral surface of a quartz chamber 120, the second quartz tube 30 and the second coil 50 are not provided in the quartz chamber 120. Therefore, a density of radicals in the first spatial region 21 tends to be uneven depending on the distance from the first coil 40. Specifically, the density of radicals is low at the center, of the first spatial region 21, which center is distant from the first coil 40.

Therefore, when a hydrogen gas and an oxygen gas by way of example are introduced as the first gas 201 from the first gas introduction port 22 into the first spatial region 21, there can be a case where hydrogen radicals as a reducing agent are deactivated. In this case, tungsten can undergo abnormal oxidation at the center part of the film 102.

On the other hand, in the present embodiment, the second quartz tube 30 and the second coil 50 are provided in the first quartz tube 20. Moreover, the second gas 202 is introduced into the second quartz tube 30 from the second gas introduction port 32 simultaneously with the introduction of the first gas 201 into the first quartz tube 20 from the first gas introduction port 22. Namely, in the semiconductor manufacturing apparatus 1 according to the present embodiment, the gases are fed from the different gas introduction ports respectively in the inner region and the outer region of the chamber to generate radicals with the individual coils. Therefore, the amounts of the radicals and the ratio of the radicals can be controlled between the inner region and the outer region.

Therefore, according to the present embodiment, controllability of generation of radicals can be improved.

(First Modification)

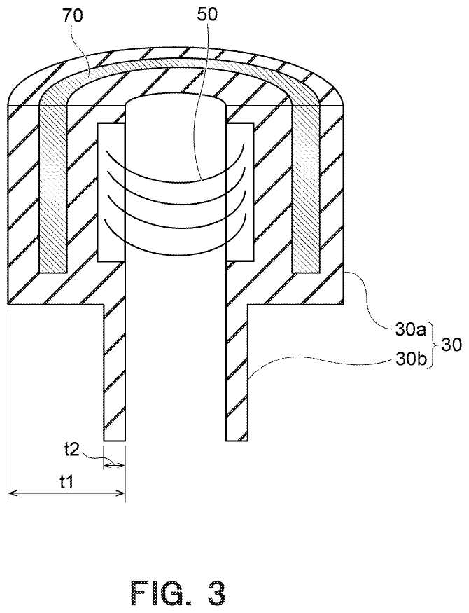

FIG. 3 is a cross sectional view showing a structure of the part of a semiconductor manufacturing apparatus according to a first modification. The similar constituents to those of the aforementioned semiconductor manufacturing apparatus 1 according to the first embodiment are given the same signs and their detailed description is omitted.

In the semiconductor manufacturing apparatus according to the present modification, as shown in FIG. 3, a magnetic body 70 encloses the second coil 50 in the first tubular part 30a of the second quartz tube 30. There can be a case where the magnetism of the second coil 50 affects the generation of plasma in the first spatial region 21. It is inferred in this case that the control of the generation of radicals in the first spatial region 21 is disturbed.

Accordingly, in the present modification, the magnetic body 70 encloses the whole second coil 50, and thereby, functions as a shield which blocks out the magnetism of the second coil 50. This function can further improve the controllability of generation of radicals in first spatial region 21.

(Second Modification)

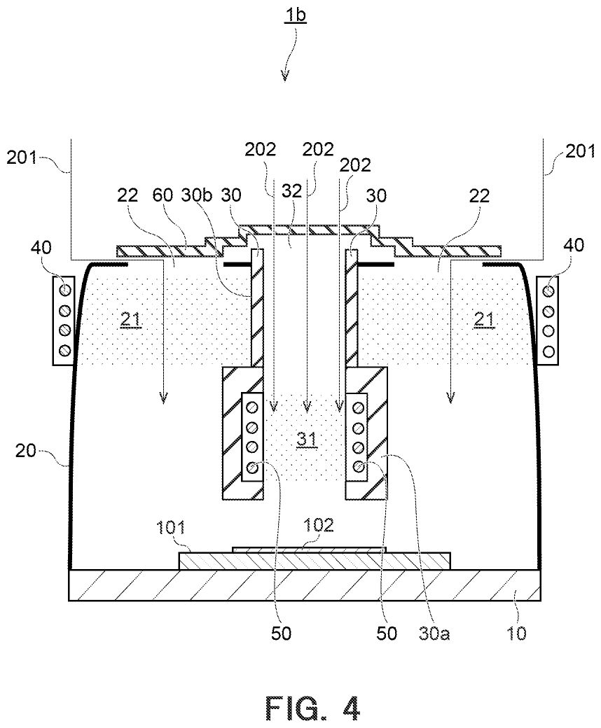

FIG. 4 is a cross sectional view showing a schematic structure of a semiconductor manufacturing apparatus according to a second modification. The similar constituents to those of the aforementioned semiconductor manufacturing apparatus 1 according to the first embodiment are given the same signs and their detailed description is omitted.

In a semiconductor manufacturing apparatus lb according to the present modification, as shown in FIG. 4, the structure of the second quartz tube 30 is different from that in first embodiment. In the first embodiment, the first tubular part 30a is arranged on the upside of the second tubular part 30b.

On the other hand, in the present modification, the first tubular part 30a and the second tubular part 30b have a reverse up-down positional relationship to that in the first embodiment. Namely, the first tubular part 30a is arranged on the downside of the second tubular part 30b.

Moreover, while in the first embodiment, the first coil 40 is arranged on the lower side of the second coil 50, both coils in the present modification have a reverse positional relationship to that in the first embodiment. Namely, the first coil 40 is arranged on the upper side of the second coil 50.

Even with the arrangement as above, the gases can be individually introduced respectively into the first spatial region 21 and the second spatial region 31 to control the generation of radicals with the individual coils.

Accordingly, also in the present modification, the controllability of generation of radicals can be improved.

### Second Embodiment

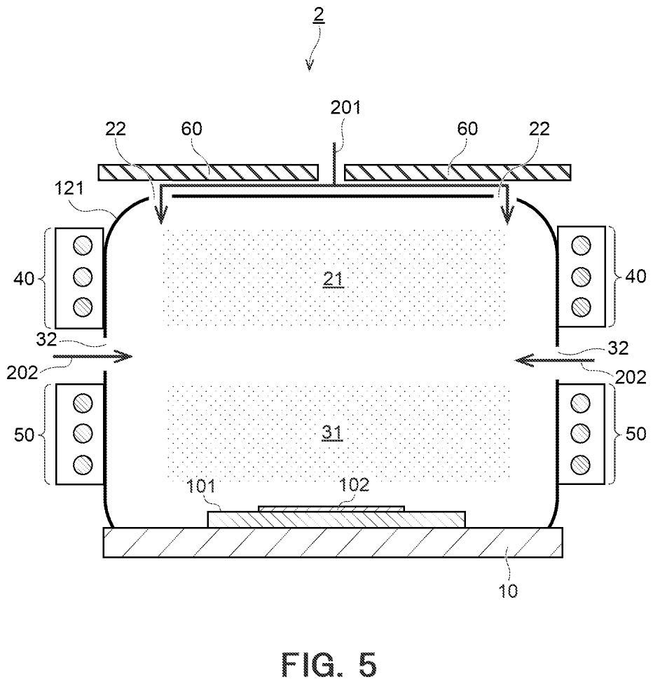

FIG. 5 is a cross sectional view showing a schematic structure of a semiconductor manufacturing apparatus according to a second embodiment. The similar constituents to those of the aforementioned semiconductor manufacturing apparatus 1 according to the first embodiment are given the same signs and their detailed description is omitted.

In a semiconductor manufacturing apparatus 2 according to the present embodiment, the first coil 40 encloses a lateral surface of a quartz chamber 121. Moreover, the second coil 50 encloses a lateral surface of the quartz chamber 121 below the first coil 40. Furthermore, the second gas introduction port 32 is provided between the first coil 40 and the second coil 50.

The second gas 202 that is more easily made into radicals than the first gas 201 is introduced to the second gas introduction port 32. For example, when the first gas 201 is a helium (He) gas, the second gas 202 is an oxygen gas.

In the present embodiment, power for the first coil 40 is larger than power for the second coil 50 in order to adjust the amounts of generation of radicals individually in the first spatial region 21 and the second spatial region 31. Specifically, the current flowing through the first coil 40 is larger than the current flowing through the second coil 50. Otherwise, the coil length of the first coil 40 is larger than the coil length of the second coil 50. Otherwise, the coil diameter of the first coil 40 is larger than the coil diameter of the second coil 50. Otherwise, the first coil 40 is arranged on the inner side of the lateral surface of the quartz chamber 121, and the second coil 50 is arranged on the outer side of the lateral surface of the quartz chamber 121.

Hereafter, there is a described comparison between the semiconductor manufacturing apparatus 2 according to the present embodiment and the semiconductor manufacturing apparatus 100 according to the comparative example shown in FIG. 2.

When with the semiconductor manufacturing apparatus 100 according to the comparative example, the first gas 201 having an oxygen gas and a helium gas mixed is introduced from the first gas introduction port 22 into the quartz chamber 120 in the state where electricity is conducted through the first coil 40, radicals of each of the oxygen gas and the helium gas are generated in the first spatial region 21. Under the same plasma conditions, a helium gas is more scarcely made into radicals than an oxygen gas. Therefore, there arises a difference in amount of generation of radicals between the helium gas and the oxygen gas, which can cause a case where this difference in amount of generation affects oxidation processing on the film 102.

On the other hand, in the present embodiment, simultaneously with introduction of the first gas 201 from the first gas introduction port 22 into the quartz chamber 121, the second gas 202 of a different kind from the first gas 201 is introduced from the second gas introduction port 32 into the quartz chamber 121. In the quartz chamber 121, the amount of generation of radicals from the first gas 201 and the amount of generation of radicals from the second gas 202 can be individually controlled by adjusting the power for each of the first coil 40 and the second coil 50.

Therefore, according to the present embodiment, the controllability of generation of radicals can be improved even when different kinds of gases are simultaneously introduced.

(Third Modification)

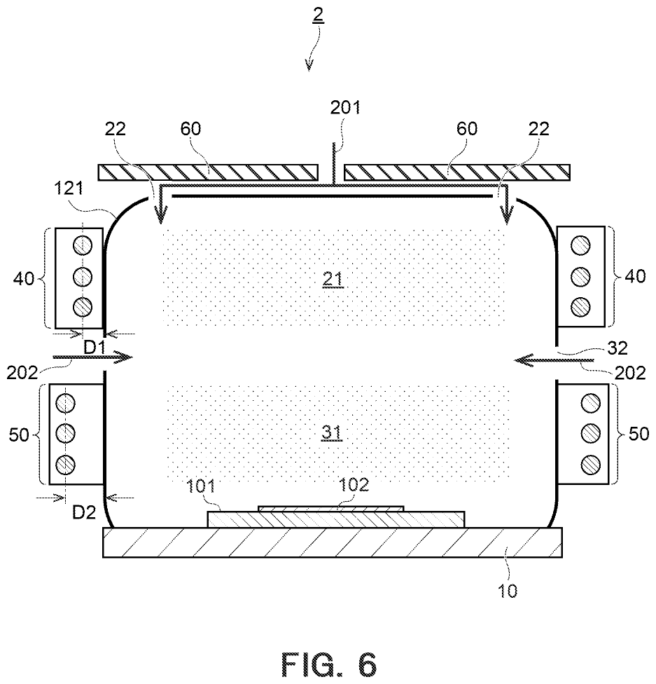

FIG. 6 is a cross sectional view showing a schematic structure of a semiconductor manufacturing apparatus according to a third modification. The similar constituents to those of the aforementioned semiconductor manufacturing apparatus 2 according to the second embodiment are given the same signs and their detailed description is omitted.

In the semiconductor manufacturing apparatus 2 according to the present modification, a distance “D1” from the center of the first coil 40 to the lateral surface of the quartz chamber 121 is smaller than a distance “D2” from the center of the second coil 50 to the lateral surface of the quartz chamber 121. The smaller the distance to the quartz chamber 121 is, the higher the intensity of plasma is.

Therefore, in the present modification, the first coil 40 is arranged at a position closer to the quartz chamber 121 than the second coil 50, and thereby, the intensity of plasma in the first spatial region 21 is set to be higher than the intensity of plasma in the second spatial region 31. Thereby, the generation of radicals from the first gas 201 is promoted similarly to the second embodiment.

According to the present modification described above, the controllability of generation of radicals can be improved even when different kinds of gases are simultaneously introduced, similarly to the second embodiment.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A semiconductor manufacturing apparatus comprising:
a chamber that houses a semiconductor substrate; and
a plurality of coils provided on a lateral surface of the chamber, wherein
the chamber has a first spatial region enclosed above the semiconductor substrate by a first coil that is one of the plurality of coils, a first gas introduction port communicating with the first spatial region, a second spatial region enclosed by a second coil that is different from the first coil among the plurality of coils, and a second gas introduction port communicating with the second spatial region.

2. The semiconductor manufacturing apparatus according to claim 1, wherein the chamber has a first quartz tube having the first spatial region and the first gas introduction port, and a second quartz tube having the second spatial region and the second gas introduction port, and the first quartz tube and the second quartz tube have a multiple tube structure in which the first quartz tube and the second quartz tube are concentrically arranged.

3. The semiconductor manufacturing apparatus according to claim 2, further comprising a magnetic body enclosing the second coil in the second quartz tube.

4. The semiconductor manufacturing apparatus according to claim 2, wherein the second quartz tube has a first tubular part having the second spatial region, and a second tubular part protruding from the first tubular part toward the first spatial region, and a thickness of the second tubular part is smaller than a thickness of the first tubular part.

5. The semiconductor manufacturing apparatus according to claim 1, wherein
the first coil is arranged above the second coil, and
the second gas introduction port is arranged between the first coil and the second coil.

6. The semiconductor manufacturing apparatus according to claim 2, wherein the second quartz tube is arranged above a center part of the semiconductor substrate.

7. The semiconductor manufacturing apparatus according to claim 4, wherein an opening diameter of the first tubular part is equal to an opening diameter of the second tubular part.

8. The semiconductor manufacturing apparatus according to claim 4, wherein the second tubular part elongates to the same level as that of a lower end part of the first coil.

9. The semiconductor manufacturing apparatus according to claim 1, wherein the first coil is arranged below the second coil.

10. The semiconductor manufacturing apparatus according to claim 1, wherein the first coil is arranged above the second coil.

11. The semiconductor manufacturing apparatus according to claim 1, wherein a first gas is introduced to the first gas introduction port, and a second gas of the same kind as the first gas is introduced to the second gas introduction port simultaneously with the first gas.

12. The semiconductor manufacturing apparatus according to claim 11, wherein each of the first gas and the second gas is a mixture gas of an oxygen gas or a nitrogen gas with a hydrogen gas.

13. The semiconductor manufacturing apparatus according to claim 5, wherein a distance from a center of the first coil to the lateral surface of the chamber is smaller than a distance from a center of the second coil to the lateral surface.

14. The semiconductor manufacturing apparatus according to claim 1, wherein a first gas is introduced to the first gas introduction port, and a second gas of a different kind from the first gas is introduced to the second gas introduction port simultaneously with the first gas.

15. The semiconductor manufacturing apparatus according to claim 14, wherein the first gas is a helium gas, and the second gas is an oxygen gas.
